(19) United States
(12) Patent Application Publication
(10) Pub. No.: US 2012/0241870 A1
(43) Pub. Date: Sep. 27, 2012

(54) Bipolar junction transistor with surface protection and manufacturing method thereof

(75) Inventors: Chien-Ling Chan, Hsinchu City (TW); Yuh-Chyuan Wang, Zhubei City (TW); Hung-Der Su, Pingzhen City (TW)

(73) Assignee: Richtek Technology Corporation

(21) Appl. No.: 13/373,225

(22) Filed: Nov. 8, 2011

(30) Foreign Application Priority Data
Mar. 21, 2011 (TW) 100109509

(51) Int. Cl. H01L 27/06; H01L 21/8249

(52) U.S. Cl. 257/378; 438/353; 257/E27.015; 257/E21.696

(57) ABSTRACT

The present invention discloses a bipolar junction transistor (BJT) with surface protection and a manufacturing method thereof. The BJT includes: a first conductive type base, a second conductive type emitter, and a second conductive type collector, which are formed in a substrate, wherein the base is formed between and separates the emitter and the collector, and the base includes a base contact region functioning as an electrical contact node of the base; and a gate structure which is formed on the substrate between the base contact region and the second conductive type emitter.

### CROSS REFERENCE

The present invention claims priority to TW 100109509, filed on Mar. 21, 2011.

### BACKGROUND OF THE INVENTION

1. Field of Invention

The present invention relates to a bipolar junction transistor (BJT) with surface protection and a manufacturing method thereof, in particular to such BJT with a gate structure covering a part of a surface of a substrate between a base contact region and an emitter to reduce a current leakage along the surface and a method for manufacturing such BJT.

2. Description of Related Art

FIG. 1 shows a cross-section view of a BJT which is manufactured by the following steps: forming an isolation structure 12 in a P-type substrate 11, wherein the isolation structure 12 is, for example, a local oxidation of silicon (LOCOS) structure; forming an N-type collector 13, a p-type base 14 and an N-type emitter 15 in the substrate 11; forming an N-type collector contact region 16 in the collector 13; and forming a P-type base contact region 17 in the substrate 11. In the manufacturing process, if it is required for the BJT to be integrated with other metal oxide semiconductor (MOS) devices in one substrate, such as for manufacturing a bipolar complementary metal oxide semiconductor (BiCMOS) circuit, the surface of the substrate 11 may be damaged by etching steps (such as gate etching or spacer self-alignment etching) typically required for manufacturing the MOS devices. In particular, if the part of the surface of the substrate between the base contact region and emitter is damaged, a current leakage along the surface of the device may occur to reduce a current gain of the BJT device.

In view of above, to overcome the drawbacks in the prior art, the present invention proposes a BJT with surface protection and a manufacturing method thereof which provide surface protection to reduce the damage to the surface of the device, in particular to reduce the damage to a junction between the base and the emitter, such that the current leakage along the surface of the device can be reduced to enhance the current gain of the BJT device.

### SUMMARY OF THE INVENTION

The objectives of the present invention are to provide a BJT with surface protection and a manufacturing method thereof.

To achieve the foregoing objectives, the present invention provides a BJT with surface protection, comprising: a first conductive type base, a second conductive type emitter, and a second conductive type collector, which are formed in a substrate, wherein the base is formed between and separates the emitter and the collector, and the base includes a base contact region functioning as an electrical contact node of the base; and a gate structure which is formed on the substrate between the base contact region and the second conductive type emitter.

In another perspective of the present invention, it provides a method for manufacturing a BJT with surface protection, comprising: providing a substrate, and forming a first conductive type base, a second conductive type emitter, and a second conductive type collector in the substrate, wherein the base is formed between and separates the emitter and the collector, and the base includes abase contact region functioning as an electrical contact node of the base; and forming a gate structure on the substrate between the base contact region and the second conductive type emitter.

In the foregoing method, the gate structure is preferably in electrical connect with a known voltage level.

If the foregoing method is applied to manufacturing a BiCMOS device, the BJT and a MOS device can be integrated in one substrate, and common manufacturing process steps can be used to form the gate structure of the BJT and the gate structure of the MOS device without any additional manufacturing process step.

The objectives, technical details, features, and effects of the present invention will be better understood with regard to the detailed description of the embodiments below, with reference to the drawings.

### BRIEF DESCRIPTION OF THE DRAWINGS

FIG. 1 shows a cross-section view of a BJT.

FIGS. 2A-2C illustrate manufacturing process steps of a first embodiment according to the present invention.

FIGS. 3A-3E show a second embodiment according to the present invention.

FIG. 4 shows a third embodiment according to the present invention.

FIG. 5 shows a fourth embodiment according to the present invention.

FIG. 6 shows a fifth embodiment according to the present invention.

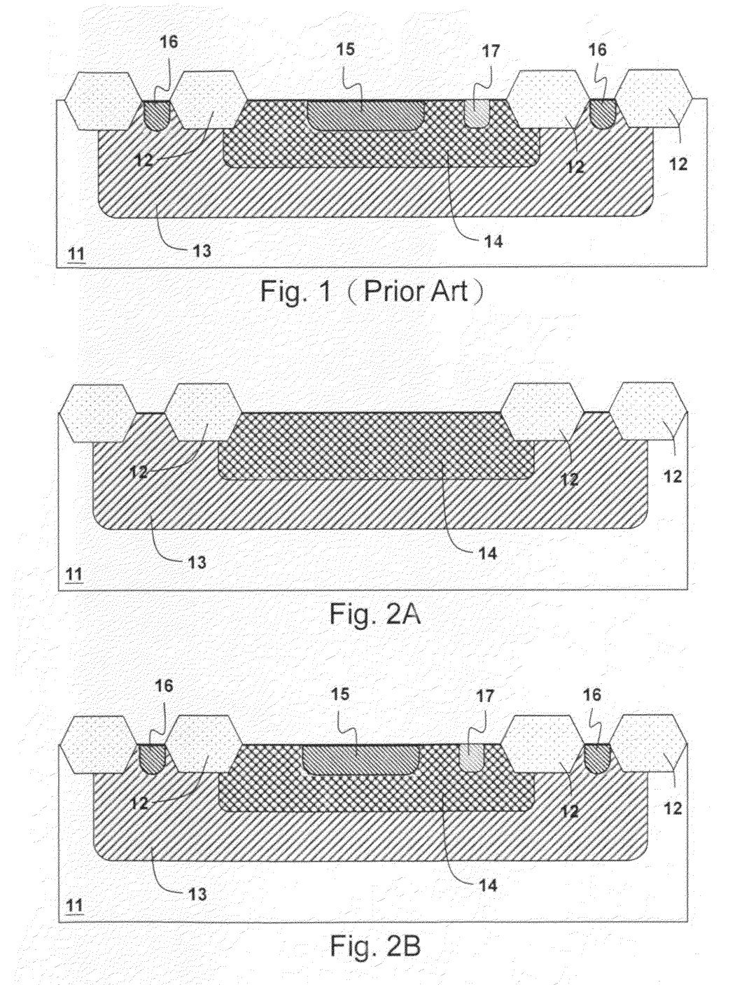

### DESCRIPTION OF THE PREFERRED EMBODIMENTS

The drawings as referred to throughout the description of the present invention are for illustration only, to show the interrelations between the regions and the process steps, but not drawn according to actual scale.

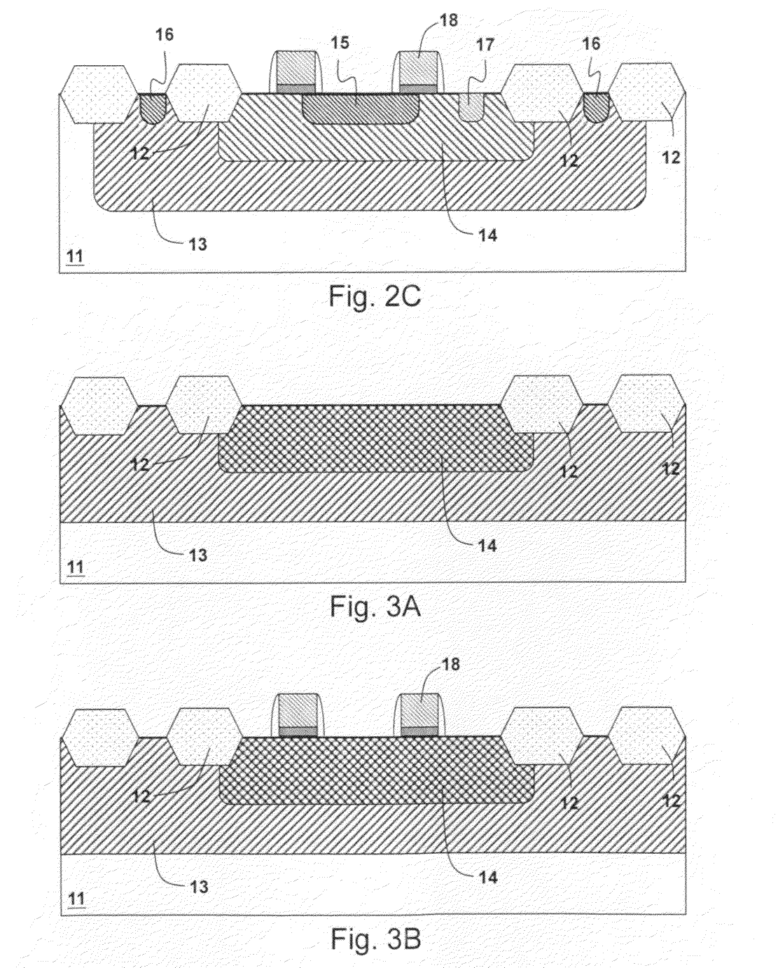

Please refer to FIGS. 2A-2C for manufacturing process steps for a first embodiment according to the present invention by cross section views. First, as shown in FIG. 2A, a first conductive type substrate 11 (for example but not limited to a P-type substrate) is provided, and a second conductive type collector 13, a second conductive type base 14, and an isolation structure 12 are formed in the substrate 11, wherein the isolation structure 12 is, for example, a LOCOS or a shallow trench isolation (STI) structure, the former being shown in the figure. Next, as shown in FIG. 2B, a second conductive type emitter 15, a second conductive type collector contact region 16 and a first conductive type base contact region 17 are formed in the substrate 11, wherein the base 14 is formed between and separates the emitter 15 and the collector 13, and the base 14 includes the base contact region 17 functioning as an electrical contact node of the base 14. Next, as shown in FIG. 2C, a gate structure 18 is formed on the substrate 11, which covers a part or all of the surface of the substrate 11 between the base contact region 17 and the emitter 15, and preferably covers a boundary between the base 14 and the emitter 15. The collector 13, base 14, emitter 15, collector contact region 16 and base contact region 17 can be formed by lithography processes and ion implantation processes, wherein a lithography process defines the implantation regions by a photoresist mask together with a self-alignment effect provided by all or a part of a gate structure 18 and the isolation structure 12, and an ion implantation process implants impurities to the defined regions. The isolation structure 12 separates the collector contact region 16 and the base 14.

With the protection by the gate structure 18, the part of the surface of the substrate 11 between the base contact region 17 and the emitter 15 is relatively less damaged by etching steps after the gate structure 18 is formed. Because the surface has fewer defects, the current leakage along the surface of the device can be reduced to improve device characteristics of the BJT when it is operating.

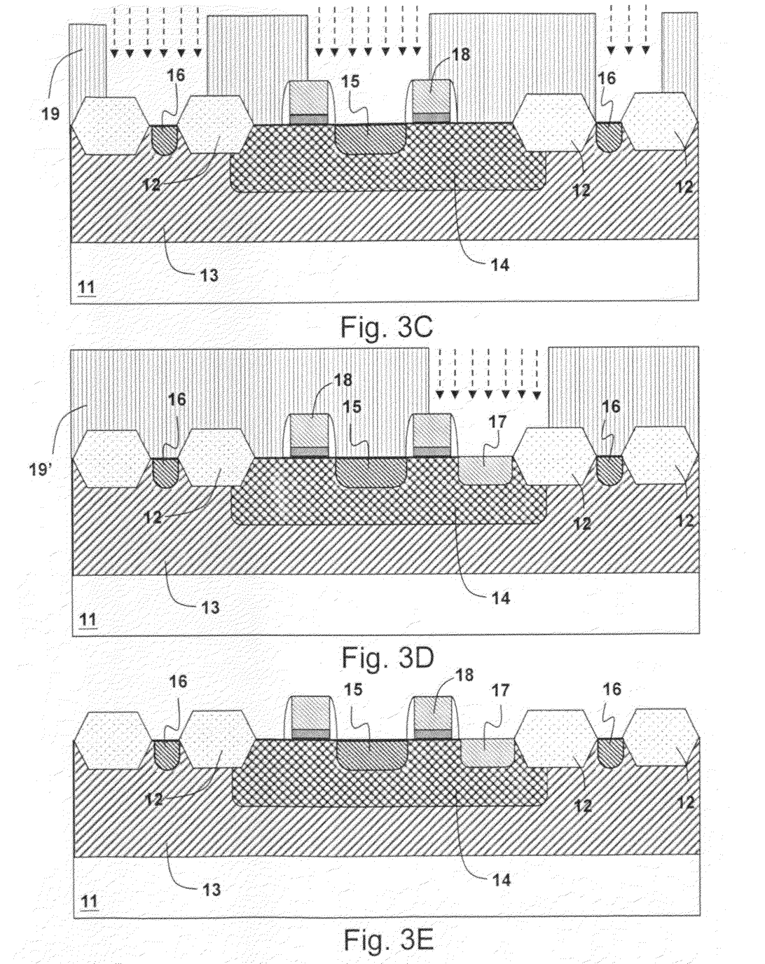

FIGS. 3A-3E show manufacturing process steps for a second embodiment according to the present invention by cross section views. Different from the first embodiment, this embodiment uses the gate structure 18, a photoresist mask 19, and/or the isolation structure 12 to define the emitter 15 and the collector contact region 16 in a manufacturing process of a BiCMOS circuit. First, as shown in FIG. 3A, a first conductive type substrate 11 (for example but not limited to a P-type substrate) is provided, and the second conductive type collector 13, the second conductive type base 14, and the isolation structure 12 are formed in the substrate 11, wherein the isolation structure 12 is, for example, a LOCOS or STI structure (the former being shown in the figure), and the collector 13 can be formed by, for example, a second conductive type epitaxial layer at the upper side of the substrate 11.

Next, as shown in FIG. 3B, the gate structure 18 is formed on the substrate 11, preferably by common manufacturing process steps for forming a gate structure in a CMOS region in the same substrate 11. Then, as shown in FIG. 3C, the second conductive type emitter 15 and the second conductive type collector contact region 16 are formed by a lithography process and an ion implantation process, wherein lithography process defines the implantation regions by the photoresist mask 19 together with a self-alignment effect provided by all or a part of the gate structure 18 and the isolation structure 12, and the ion implantation process implants second conductive type impurities to the substrate 11 as illustrated by the dashed arrows in this figure. The photoresist mask 19 preferably also defines second conductive type regions (for example but not limited to second conductive type source and drain) in the CMOS region in the same substrate 11. The ion implantation process for the emitter 15 and the collector contact region 16 is preferably the same process for forming the second conductive type regions (for example but not limited to the second conductive type source and drain) in the CMOS region.

Next, as shown in FIG. 3D, the first conductive type base contact region 17 is formed as an electrical contact node of the base 14, by a lithography process wherein the implantation region is defined by a photoresist mask 19′ together with a self-alignment effect provided by all or a part of the gate structure 18 and the isolation structure 12, and an ion implantation process (as illustrated by the dashed arrows in this figure). The lithography process and ion implantation process for forming the base contact region 17 preferably also define and forma first conductive type region (for example but not limited to a first conductive type body region) in the CMOS region. After the photoresist mask 19′ is removed, the device according to this embodiment is finished as shown by the cross-section view of FIG. 3E. In this embodiment, the gate structure 18 is used to define the base contact region 17 and the emitter 15, so the gate structure 18 covers substantially all of the surface of the substrate 11 between the base contact region 17 and the emitter 15. The isolation structure 12 separates the collector contact region 16 and the base 14.

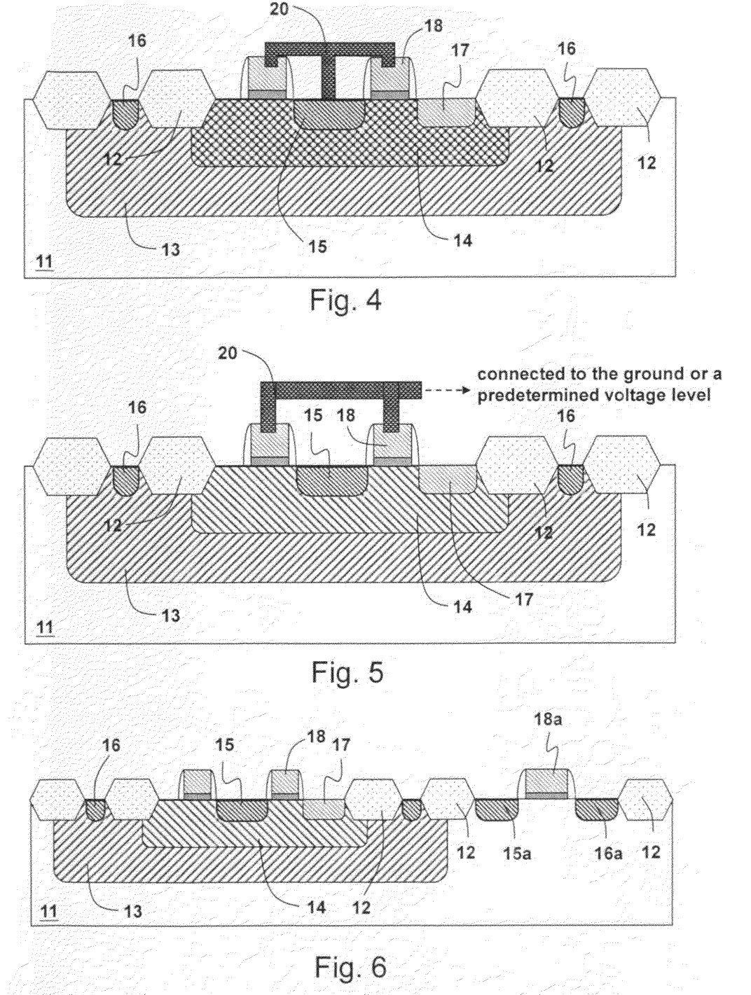

FIG. 4 shows a third embodiment according to the present invention. Different from the second embodiment, the gate structure 18 electrically connects to the emitter 15 via a wire 20.

FIG. 5 shows a fourth embodiment according to the present invention. Different from the second embodiment, the gate structure 18 electrically connects to the ground or a predetermined voltage level via a wire 20. In fact, the gate structure 18 in the present invention is used to prevent the surface of the substrate 11 from being damaged in the manufacturing process, and it is not designed for providing any circuital function, so the voltage level of the gate structure 18 is not important. However, in order for the gate structure 18 not to be floating, to avoid any unnecessary interference caused by the uncontrollable unknown voltage level of the gate structure 18, it is preferable for the gate structure 18 to be connected to a known voltage level.

FIG. 6 shows a fifth embodiment according to the present invention. This embodiment shows that a BJT can be formed in a manufacturing process for a MOS device. In other words, the BJT and the MOS can be integrated in one substrate 11. For example, common manufacturing process steps for forming the gate structure 18a of the MOS device can be used to form the gate structure 18 of the BJT, so no additional manufacturing process step is required. Likely, the collector 13, base 14, emitter 15, collector contact region 16 and base contact region 17 can be formed respectively by, for example but not limited to, common manufacturing process steps for a second conductive type well (not shown), a first conductive type well (not shown), a second conductive type source 15a, a second conductive type drain 16a and a first conductive type body region (not shown) of the MOS device, without any additional process step.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other manufacturing process steps or structures which do not affect the characteristics of the devices, such as a deep-well region, etc., can be added. As another example, the lithography process is not limited to photolithography; it can be electron beam lithography, X-ray lithography or other methods. As yet another example, the present invention is also applicable to other BJT devices with different structures and layouts, such as a BJT device without the isolation structure, so the structures and layouts shown in the above embodiments are not limitations to the present invention. Thus, the present invention should cover all such and other modifications and variations, which should be interpreted to fall within the scope of the following claims and their equivalents.

What is claimed is:

1. A bipolar junction transistor (BJT) with surface protection, comprising:
a first conductive type base, a second conductive type emitter, and a second conductive type collector, which are formed in a substrate, wherein the base is formed between and separates the emitter and the collector, and the base includes a base contact region functioning as an electrical contact node of the base; and
a gate structure which is formed on the substrate between the base contact region and the second conductive type emitter.

2. The BJT of claim 1, wherein the gate structure electrically connects to the emitter, a ground or a predetermined voltage level.

3. The BJT of claim 1, wherein the substrate further includes a metal oxide semiconductor (MOS) device which has another gate structure formed by at least one common process step of the gate structure.

4. The BJT of claim 1, further comprising:
a second conductive type collector contact region formed in the collector; and
at least one isolation structure separating the collector contact region and the base.

5. A method for manufacturing a bipolar junction transistor (BJT) with surface protection, comprising:
providing a substrate, and forming a first conductive type base, a second conductive type emitter, and a second conductive type collector in the substrate, wherein the base is formed between and separates the emitter and the collector, and the base includes a base contact region functioning as an electrical contact node of the base; and
forming a gate structure on the substrate between the base contact region and the second conductive type emitter.

6. The method of claim 5, wherein the gate structure electrically connects to the emitter, a ground or a predetermined voltage level.

7. The method of claim 5, wherein the substrate further includes a metal oxide semiconductor (MOS) device which has another gate structure formed by at least one common process step of the gate structure.

8. The method of claim 5, further comprising:
forming a second conductive type collector contact region in the collector; and
forming at least one isolation structure separating the collector contact region and the base.
